(19) United States
(12) Patent Application Publication
(10) Pub. No.: US 2015/0076697 A1
(43) Pub. Date: Mar. 19, 2015

(54) DUMMY BARRIER LAYER FEATURES FOR PATTERNING OF SPARSELY DISTRIBUTED METAL FEATURES ON THE BARRIER WITH CMP

(71) Applicant: KLA-Tencor Corporation, Milpitas, CA (US)

(72) Inventors: Tomas Plettner, San Ramon, CA (US); Mehran Nasser-Ghodsi, Hamilton, MA (US); John Gerling, Livermore, CA (US)

(21) Appl. No.: 14/485,574

(22) Filed: Sep. 12, 2014

Related U.S. Application Data
(60) Provisional application No. 61/878,606, filed on Sep. 17, 2013.

(51) Int. Cl. H01L 21/768; H01L 23/532; H01L 23/522

(52) U.S. Cl. CPC H01L 21/76843; H01L 23/5226; H01L 23/53266
USPC 257/751; 438/653

(57) ABSTRACT

A semiconductor device comprises a plurality of device features formed on a substrate and a plurality of dummy features formed on the substrate and across an open region between the device features. Adjacent device features are spaced apart by a distance of 100 microns or more. Each device feature includes a barrier island and a metal layer on top of the barrier island. Each dummy feature has a structure that corresponds to the structure of the barrier island. This abstract is provided to comply with rules requiring an abstract that will allow a searcher or other reader to quickly ascertain the subject matter of the technical disclosure. It is submitted with the understanding that it will not be used to interpret or limit the scope or meaning of the claims.

### CLAIM OF PRIORITY

This application is a nonprovisional of and claims the priority benefit of commonly owned, co-pending U.S. Provisional Patent Application No. 61/878,606, to Tomas Plettner et al., filed Sep. 17, 2013, and entitled “DUMMY BARRIER LAYER FEATURES FOR PATTERNING OF SPARSELY DISTRIBUTED METAL FEATURES ON THE BARRIER WITH CMP” the entire disclosures of which are incorporated herein by reference.

### FIELD OF THE DISCLOSURE

Aspects of the present disclosure are related to semiconductor devices and methods for manufacturing them, and more particularly, to a semiconductor device structure with dummy features for improving the manufacturing process.

### BACKGROUND OF THE INVENTION

Planarization is important in semiconductor manufacturing process. As the sizes of semiconductor devices decrease, highly integrated semiconductor devices typically include stacked material layers and related interconnections. Unevenness or irregularity of the substrate or material layers may cause undesirable effects in the ultimate device. Thus, more severe constraints on the degree of planarity are required of the processing surface of a semiconductor wafer to achieve high resolution semiconductor feature patterns.

Chemical mechanical polishing (CMP) is increasingly being used as a planarizing process for semiconductor device layers, especially for devices having multi-level design and smaller semiconductor fabrication processes. In CMP, a polishing pad is applied with an abrasive and corrosive chemical known as “slurry”. A processing surface is pressed against the rotating polishing pad. The pressure applied through the pad and the chemical reaction from slurry remove excess materials and even out any irregular topography and thus making the processing surface flat or planar.

CMP planarization is typically used in several different stages in the manufacture of a multi-level semiconductor device, including planarizing levels of a device containing both dielectric and metal portions to achieve global planarization for subsequent processing of overlying levels. However, over-polishing, under-polishing or uneven polishing may happen when different rates of polishing (i.e., the respective rates of material removal) arise for different materials forming a processing surface or for a processing surface with regions of densely arranged patterns and sparsely arranged patterns. Under these circumstances, a flat or planar surface cannot be achieved, ultimately affecting device performance.

It is within this context that aspects of the present disclosure arise.

### SUMMARY

According to aspects of the present disclosure, a semiconductor device comprises a plurality of device features formed on a substrate and a plurality of dummy features formed on the substrate and across an open region between the device features. Adjacent device features are spaced over 100 microns apart. Each device feature includes a barrier island and a metal layer on top of the barrier island. Each dummy feature has dimensions corresponding to those of the barrier island.

In some implementations, the barrier island may be made from titanium nitride (TiN), titanium (Ti), indium tin oxide (ITO) or silicon dioxide (SiO₂).

In some implementations, the metal layer may be made from Nickel (Ni), Chromium (Cr), Iron (Fe) or Gold (Au).

In some implementations, two adjacent dummy features may be spaced apart by a distance approximately equal to a characteristic size of the dummy feature.

In some implementations, each device feature further includes a carbon nanotube formed on top of the metal layer.

According to aspects of the present disclosure, a method comprises forming a barrier layer on a substrate; patterning the barrier layer to form a plurality of first barrier islands and second barrier islands identical to the first barrier islands; forming an oxide layer over the first and second barrier islands and the substrate; patterning the oxide layer to expose the first barrier islands; depositing a metal layer over the exposed first barrier islands and the oxide layer; and performing CMP processing on the metal layer so that only portions of the metal layer on top of the first barrier islands is left to form the device features. The first barrier islands are provided at locations of the device features to be formed and the second barrier islands are provided across an open region between the device features to be formed.

### BRIEF DESCRIPTION OF THE DRAWINGS

Objects and advantages of the invention will become apparent upon reading the following detailed description and upon reference to the accompanying drawings in which:

FIGS. 1A-1C are cross-sectional views showing a prior art method for patterning sparsely distributed device features.

FIG. 2 is a top view showing a semiconductor device with sparsely distributed device features according to one embodiment of the present disclosure.

FIGS. 3A-3G are cross-section views showing a method for patterning sparsely distributed device features according to one embodiment of the present disclosure.

### DETAILED DESCRIPTION

In the following Detailed Description, reference is made to the accompanying drawings, which form a part hereof, and in which is shown by way of illustration specific embodiments in which the invention may be practiced. The drawings show illustrations in accordance with examples of embodiments, which are also referred to herein as “examples”. The drawings are described in enough detail to enable those skilled in the art to practice the present subject matter. Because components of embodiments of the present invention can be positioned in a number of different orientations, directional terminology is used for purposes of illustration and is in no way limiting. It is to be understood that other embodiments may be utilized and structural or logical changes may be made without departing from the scope of the present invention.

In this document, the terms “a” and “an” are used, as is common in patent documents, to include one or more than one. In this document, the term “or” is used to refer to a nonexclusive “or,” such that “A or B” includes “A but not B,” “B but not A,” and “A and B,” unless otherwise indicated. The following detailed description, therefore, is not to be taken in a limiting sense, and the scope of the present invention is defined by the appended claims.

### Introduction

For some semiconductor devices such as field emission devices, the features on the substrate are required to be spaced apart. As one application, field emission devices may provide a source of bright electrons for high-resolution electron microscopes. A conventional field emission device comprises a cathode and an anode spaced from the cathode. The cathode may be a field emitter array including a plurality of field emitters. A voltage applied between the anode and cathode induces the emission of electrons towards the anode. Carbon nanotubes (CNTs) have increasingly being utilized as a material for electron field emitters because of their high electrical conductivity, high aspect ratio “needle like” shape for optimum geometrical field enhancement, and remarkable thermal stability. When two field emitters are placed too close to each other, the electric field would be reduced. Thus, two adjacent field emitters in the field emitter array have to be spaced apart, e.g., over 100 microns. Since there is a large spacing between the device features (i.e., the emitters), it would result in uneven processing surfaces during CMP processing.

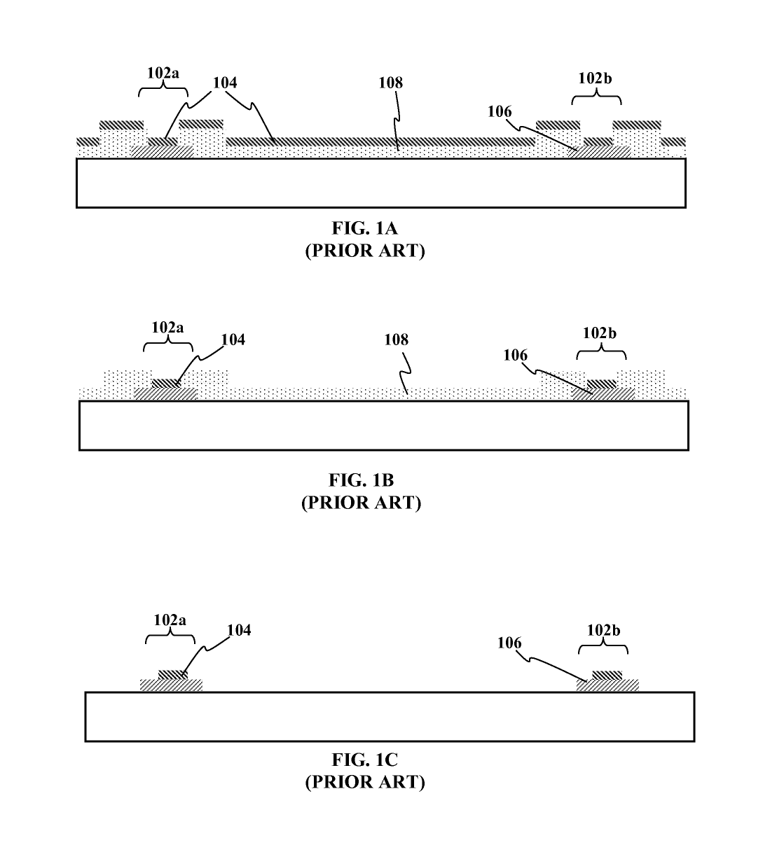

FIGS. 1A-1C shows a prior art method for patterning sparsely distributed device features. In FIG. 1A, device features (e.g., 102a and 102b) made of metal 104 over barrier islands 106 are sparsely distributed. The distance between two adjacent device features 102a and 102b is over 100 microns. In FIG. 1B, a CMP process is performed to remove portions of the metal layer 104 to expose oxide layer 108 as shown in FIG. 1B. Thereafter, the exposed oxide layer 108 are removed through oxide etching as shown in FIG. 1C. However, since there is a large spacing between the device features, the polishing rates for the area with the device features and the area between two adjacent features are different. Thus, CMP processing may not be uniform and controllable to form device features with controlled thickness or shape.

One proposed method to overcome uneven CMP loading provides a blanket barrier layer over the oxide layer 108. After the metal deposition, portions of the barrier layer are then etched away. However, problems may arise in stripping the resist after etching.

A semiconductor device according to present disclosure includes a uniform dense array of barrier islands across the entire open region between the metal features. This structure provides a uniform loading across the die for CMP processing and thus improving non-uniformity caused by uneven CMP loading from the sparsely distributed device features.

### Embodiments

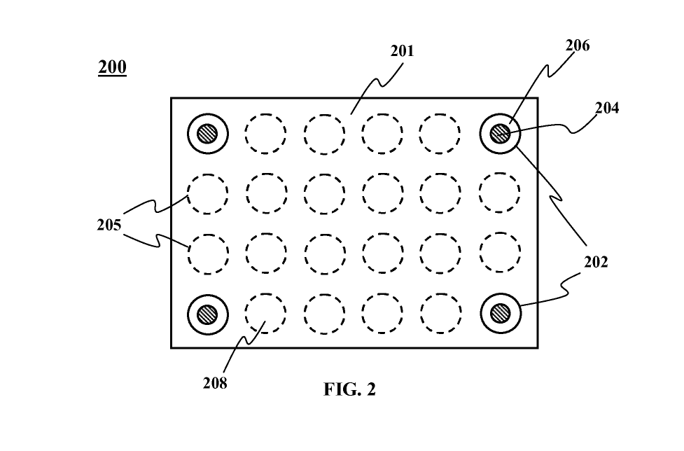

FIG. 2 is a top view of a semiconductor device according to an aspect of the present disclosure. The semiconductor device 200 of FIG. 2 includes a plurality of device features 202 and one or more dummy features 205 on a substrate 201. By way of example, in device 200, adjacent device features 202 are spaced apart by a distance of over 100 microns, e.g., between about 100 microns and about 1 millimeter (1000 microns). In one implementation, the space between two adjacent device features is between about 100 microns and about 500 microns. Each device feature 202 includes a barrier island 206 and a metal layer 204 formed on top of the barrier island 206. The one or more dummy features are formed between two adjacent device features. Each of the one or more dummy features includes a dummy island 208 that is identical to the barrier islands 206.

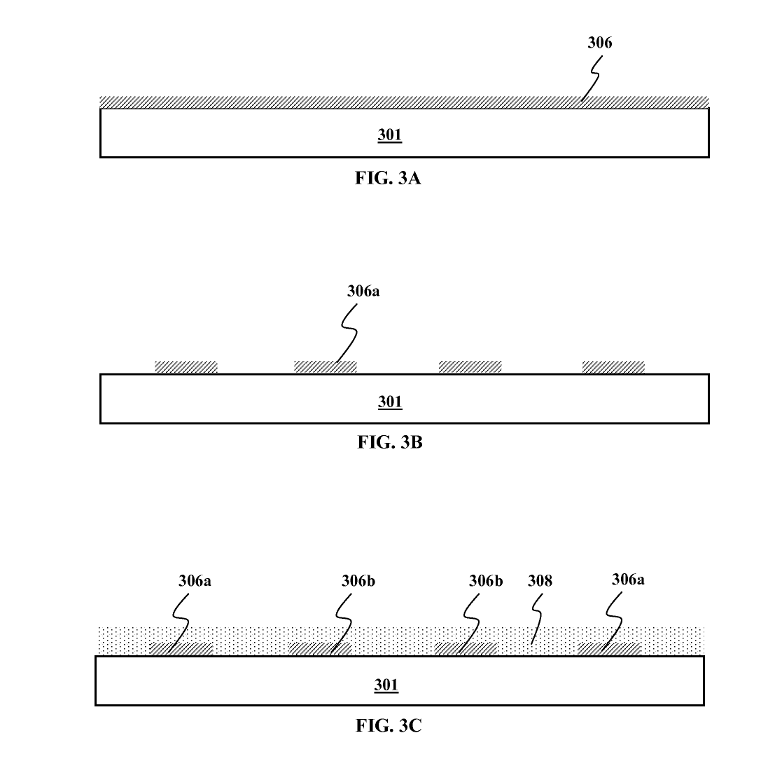

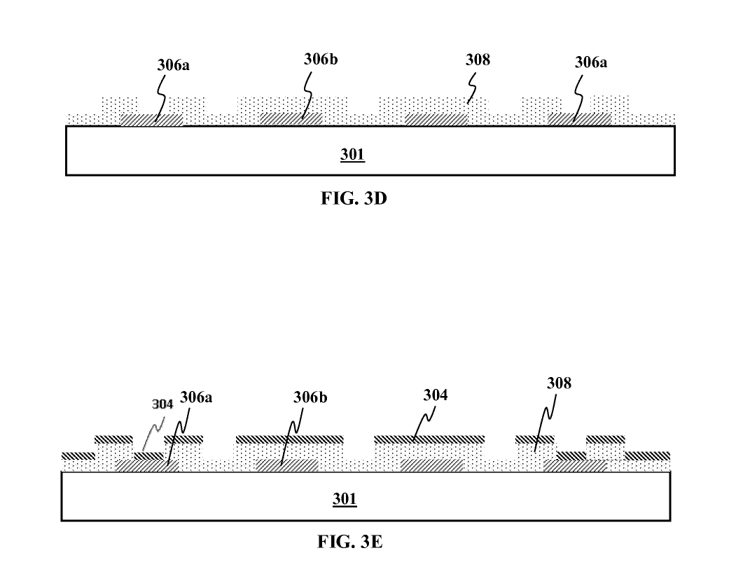

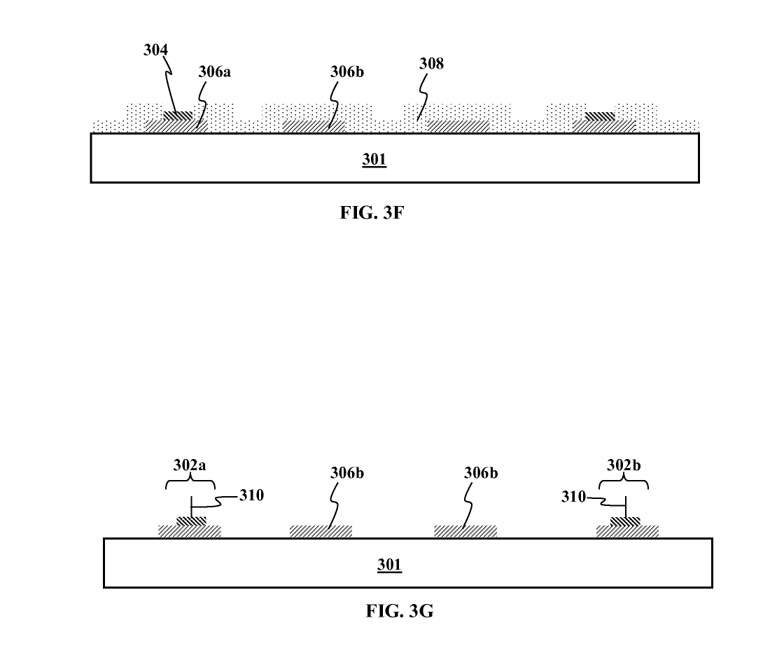

FIGS. 3A-3G are cross sectional views showing a method for forming a device with sparsely distributed device features according to an aspect of the present disclosure. With reference to FIG. 3A, a substrate 301 is provided. In one implementation, the substrate 301 is made from lightly doped silicon. A barrier layer 306 is formed on top of the substrate 301 by blanket deposition. In field emission devices, a barrier layer is usually provided to prevent diffusion. In one implementation, the barrier layer 306 is made from titanium nitride (TiN), titanium (Ti), indium tin oxide (ITO) or silicon dioxide (SiO₂). In FIG. 3B, the barrier layer 306 is then patterned to form a number of identical barrier islands 306a and 306b through etching process. The barrier islands are not only formed at the locations of the device features (e.g., the barrier islands 306a) but also across the entire empty region between the device features (e.g., the barrier islands 306b). In one implementation, the barrier islands 306a and 306b are in a size about 1 micron. With the barrier islands 306b provided across the empty regions between the device features, the loading on the CMP becomes uniform. It should be noted that the barrier layer 306 needs not be patterned in an array format. In addition, the barrier islands 306a and 306b can be in any shape as long as the barrier islands 306a and 306b are not continuous as a layer. A continuous barrier layer would introduce a large surface tension, and thus it is desirable to include trenches or other discontinuities between the islands 306a and 306b to relieve the surface stress.

With reference to FIG. 3C, oxidation is performed to form a mask layer 308 over the structure of FIG. 3B. In one implementation, the mask layer 308 is made from SiO₂. Other materials may be used in alternative implementations. In FIG. 3D, the mask layer 308 is patterned to expose portions of only the barrier islands 306a at the locations of device features. FIG. 3E shows a metal layer 304 is then deposited over the barrier islands 306a and the mask layer 308. In example of field emission devices, the metal layer is used as a catalyst for growing carbon nanotubes 310, as shown in FIG. 3G, or other nanostructures for a field emitter on top of it. By way of example and not by way of limitation, the metal layer 304 may be made from Nickel (Ni), Chromium (Cr), Iron (Fe) for nanotubes or Gold (Au) for other nanostructures. The metal layer 304 is formed such that there is no metal in the spaces between adjacent barrier islands 306b or in a space between a barrier islands and an adjacent device feature. A CMP process is then performed to remove portions of the metal layer 304 as shown in FIG. 3F. The mask layer 308 is then removed by wet etching. The device features 302a and 302b are thus formed as shown in FIG. 3G. The barrier islands 306b act as dummy features formed between the device features present a uniform mechanical load to the CMP to prevent over- or under-polishing. The spacing between the adjacent dummy features (i.e., the barrier islands 306b) is about the same as the size of the dummy features, e.g., 1 micron. By way of example, and not by way of limitation, size of the metal features 304 on top of the barrier islands 306a is about 100 nm in the critical dimension (CD) e.g., width or diameter. It should be noted that the barrier islands 306a that support the metal features 304 can be as small as the metal features or larger. In the application of field emission devices, carbon nanotubes or other nanostructures may be formed on top of the metal features 304.

In certain implementations, the above-described method may utilize dummy features that are of substantially the same structure as the barrier islands of the device features. Furthermore, the dummy features may be formed at the same stage of manufacture as barrier islands of the device features. Thus, with modification of the pattern layout of the barrier layer to incorporate the dummy features, the method leaves the pattern layout and the patterning process that forms the sparsely arranged device features largely unchanged. The dummy features provide a uniform mechanical load for the CMP process for sparsely distributed device features. Aspects of the present disclosure thus allow for economical manufacture of sparse arrays of devices such as field emitters through the use of CMP at an intermediate stage of manufacture.

While the above includes a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents.

The appended claims are not to be interpreted as including means-plus-function limitations, unless such a limitation is explicitly recited in a given claim using the phrase “means for.” Any element in a claim that does not explicitly state “means for” performing a specified function, is not to be interpreted as a “means” or “step” clause as specified in 35 USC §112(f). In particular, the use of “step of” in the claims herein is not intended to invoke the provisions of 35 USC §112(f).

What is claimed is:

1. A semiconductor device, comprising:
a plurality of device features formed on a substrate, wherein each device feature includes a barrier island and a metal layer on top of the barrier island and wherein adjacent device features are spaced apart by a distance of 100 microns or more; and
a plurality of dummy features formed on the substrate and across an open region between and among the device features of the plurality, wherein a structure of each dummy corresponds to a structure to the barrier island.

2. The device of claim 1, wherein the barrier island is made from titanium nitride (TiN), titanium (Ti), indium tin oxide (ITO) or silicon dioxide (SiO₂).

3. The device of claim 1, wherein the metal layer is made from Nickel (Ni), Chromium (Cr), Iron (Fe) or Gold (Au).

4. The device of claim 1, wherein two adjacent dummy features are spaced apart by a distance approximately equal to a characteristic size of the dummy feature.

5. The device of claim 1, wherein each device feature further includes an emitter structure formed on top of the metal layer.

6. The device of claim 1, wherein the emitter structure includes a carbon nanotube.

7. The device of claim 6, wherein the substrate is a doped semiconductor material.

8. The device of claim 1, wherein adjacent device features are spaced apart by a distance between about 100 microns and about 1 millimeter (1000 microns). In one implementation.

9. The device of claim 1, wherein adjacent device features are spaced apart by a distance between about 100 microns and about 500 microns.

10. A method, comprising:
forming a barrier layer on a substrate;
patterning the barrier layer to form a plurality of first barrier islands and second barrier islands identical to the first barrier islands, wherein the first barrier islands are provided at locations of device features to be formed and the second barrier islands are provided across an open region between the device features to be formed;
forming an oxide layer over the first and second barrier islands and the substrate;
patterning the oxide layer to expose the first barrier islands;
depositing a metal layer over the exposed first barrier islands and the oxide layer; and
performing chemical mechanical polishing (CMP) on the metal layer so that only portions of the metal layer on top of the first barrier islands are left to form the device features.

11. The method of claim 10, wherein the barrier layer is made from titanium nitride (TiN), titanium (Ti), indium tin oxide (ITO) or silicon dioxide (SiO₂).

12. The method of claim 10, wherein the metal layer is made from Nickel (Ni), Chromium (Cr), Iron (Fe) or Gold (Au).

13. The method of claim 10, wherein two adjacent second barrier islands are spaced apart by a distance approximately equal to a characteristic size of the second barrier island.

14. The method of claim 10, wherein two adjacent dummy features are spaced apart by a distance approximately equal to a characteristic size of the dummy feature.

15. The method of claim 10, further comprising forming an emitter structure on the metal layer the metal layer on top of one or more of the first barrier islands.

16. The method of claim 10, wherein the emitter structure includes a carbon nanotube.

17. The method of claim 16, wherein the substrate is a doped semiconductor material.

18. The method of claim 10, wherein adjacent device features are spaced apart by a distance between about 100 microns and about 1 millimeter (1000 microns). In one implementation.

19. The method of claim 10, wherein adjacent device features are spaced apart by a distance between about 100 microns and about 500 microns.
